(19) United States
(12) Patent Application Publication
(10) Pub. No.: US 2018/0076374 A1
(43) Pub. Date: Mar. 15, 2018

(54) Thermoelectric Generator

(71) Applicant: KELK Ltd., Hiratsuka-shi (JP)

(72) Inventors: Kazuya Makino, Hiratsuka-shi (JP); Haruo Imamura, Hiratsuka-shi (JP); Hirokuni Hachiuma, Hiratsuka-shi (JP)

(21) Appl. No.: 15/262,337

(22) Filed: Sep. 12, 2016

(51) Int. Cl. H01L 35/32; H01L 35/30

(52) U.S. Cl. CPC H01L 35/32; H01L 35/30

(57) ABSTRACT

A thermoelectric generator includes: a heat-receiving plate configured to receive heat; a cooling plate kept at a lower temperature than a temperature of the heat-receiving plate; and a thermoelectric generation module interposed between the heat-receiving plate and the cooling plate, the thermoelectric generation module including a plurality of thermoelectric elements, an outer sealing frame surrounding the thermoelectric elements, and a film sheet continuously entirely covering at least a first side of the thermoelectric elements and the outer sealing frame facing the heat-receiving plate; and a first heat insulation layer formed in a space that is defined between the heat-receiving plate and the thermoelectric generation module and that corresponds to the outer sealing frame.

### TECHNICAL FIELD

The present invention relates to a thermoelectric generator, specifically, to an improvement in a sealing structure of the thermoelectric generator.

### BACKGROUND ART

There has been typically known a thermoelectric generator including a heat-receiving plate, a cooling plate, and a plurality of thermoelectric generation modules interposed between the heat-receiving plate and the cooling plate (see, for instance, Patent Literature 1: JP-A-2013-080883). In the thermoelectric generator of Patent Literature 1, in order to prevent occurrence of migration and the like caused by adherence of moisture to thermoelectric elements in the thermoelectric generation modules, a resin-made O-ring having an excellent heat resistance seals a space between the heat-receiving plate and the cooling plate, thereby preventing moisture from entering the thermoelectric generation modules.

Although the sealing structure uses such a heat-resistant O-ring, heat resistance of the O-ring has a limitation. In view of this, a thermoelectric generator having a sealing structure capable of further suppressing deterioration of the O-ring by heat has been proposed (see, for instance, Patent Literature 2: JP-A-2007-258298). In the thermoelectric generator of Patent Literature 2, a metallic frame having more excellent heat resistance is used in place of the resin-made O-ring and is bonded to the heat-receiving plate and the cooling plate with an adhesive agent and the like.

However, when the metallic frame is used in place of the resin-made O-ring as described in the thermoelectric generator of Patent Literature 2, heat received in the heat-receiving plate is transferred to the cooling plate through the metallic frame, so that the heat amount transferred to the thermoelectric generation modules is decreased to significantly decrease an electric power generation efficiency.

### SUMMARY OF THE INVENTION

An object of the invention is to provide a thermoelectric generator capable of maintaining a favorable sealing performance even when the thermoelectric generator is exposed to a high heat, and preventing a decrease in an electric power generation efficiency.

According an aspect of the invention, a thermoelectric generator includes: a heat-receiving plate configured to receive heat; a cooling plate configured to be kept at a lower temperature than a temperature of the heat-receiving plate; and a thermoelectric generation module interposed between the heat-receiving plate and the cooling plate, in which the thermoelectric generation module includes: a plurality of thermoelectric elements; an outer sealing frame surrounding the thermoelectric elements; and a film sheet continuously entirely covering at least a first side facing the heat-receiving plate of the thermoelectric elements and the outer sealing frame; and a first heat insulation layer formed in a space that is defined between the heat-receiving plate and the thermoelectric generation module and that corresponds to the outer sealing frame.

In the above arrangement, it is preferable that the thermoelectric generator further includes a heat transfer layer formed between the heat-receiving plate and the thermoelectric generation module in a manner to circumvent the first heat insulation layer.

In the above arrangement, it is preferable that the thermoelectric generator further includes a fastener inserted through the heat-receiving plate, the cooling plate and the thermoelectric generation module to fasten the heat-receiving plate, the cooling plate and the thermoelectric generation module with each other, in which the thermoelectric generation module includes an inner sealing frame surrounding the fastener; and a second heat insulation layer formed in a space that is defined between the heat-receiving plate and the thermoelectric generation module and that corresponds to the inner sealing frame.

In the above arrangement, it is preferable that the thermoelectric generator further includes a heat transfer layer formed between the heat-receiving plate and the thermoelectric generation module in a manner to circumvent the first heat insulation layer and the second heat insulation layer, when the first heat insulation layer and the second heat insulation layer are formed between the heat-receiving plate and the thermoelectric generation module.

In the above arrangement, it is preferable that the thermoelectric generation module is interposed between the heat-receiving plate and the cooling plate while being pressed by the heat-receiving plate and the cooling plate, and the fastener includes a coil spring configured to apply a pressing force to the thermoelectric generation module through the heat-receiving plate and the cooling plate.

In the above arrangement, it is preferable that the outer sealing frame and/or the inner sealing frame is bonded to the film sheet.

In the above arrangement, it is preferable that the film sheet is in a form of a laminated sheet a first surface made of an electrically insulative material and a second surface made of a low gas (moisture) permeable material, more specifically, the film sheet includes film sheets each including a polyimide film and a copper film entirely covering one surface of the polyimide film, and the film sheets are respectively provided on the first side facing the heat-receiving plate and a second side facing the cooling plate of the thermoelectric elements and the outer sealing frame with the respective copper films facing the heat-receiving plate and the cooling plate.

According to the above aspect of the invention, with use of the outer sealing frame (e.g., metallic frame) in place of the typical resin-made O-ring, the thermoelectric generator can be further improved in heat resistance to maintain a favorable sealing performance even when the thermoelectric generator is exposed to high heat. Moreover, since a first heat insulation layer is formed in a space that is defined between the heat-receiving plate and the thermoelectric generation module and that corresponds to the outer sealing frame, the heat received in the heat-receiving plate is prevented from being transferred to the outer sealing frame, so that the heat amount to be transferred to the cooling plate through the outer sealing frame can be significantly reduced to improve the electric power generation efficiency.

### BRIEF DESCRIPTION OF DRAWINGS

FIG. 1 is an exploded perspective view of a thermoelectric generator according to a first exemplary embodiment of the invention.

FIG. 2 is a cross-sectional view of the thermoelectric generator.

FIG. 3 is an exploded perspective view of a thermoelectric generation module used in the thermoelectric generator.

FIG. 4 is an enlarged cross-sectional view of a relevant portion of the thermoelectric generator.

FIG. 5 is a cross-sectional view showing a second exemplary embodiment of the invention.

FIG. 6A is a cross-sectional view showing a modification of an outer sealing frame of the invention.

FIG. 6B is a cross-sectional view showing another modification of the outer sealing frame of the invention.

FIG. 6C is a cross-sectional view showing still another modification of the outer sealing frame of the invention.

### DESCRIPTION OF EMBODIMENT(S)

### First Exemplary Embodiment

A first exemplary embodiment of the invention will be described below with reference to the attached drawings.

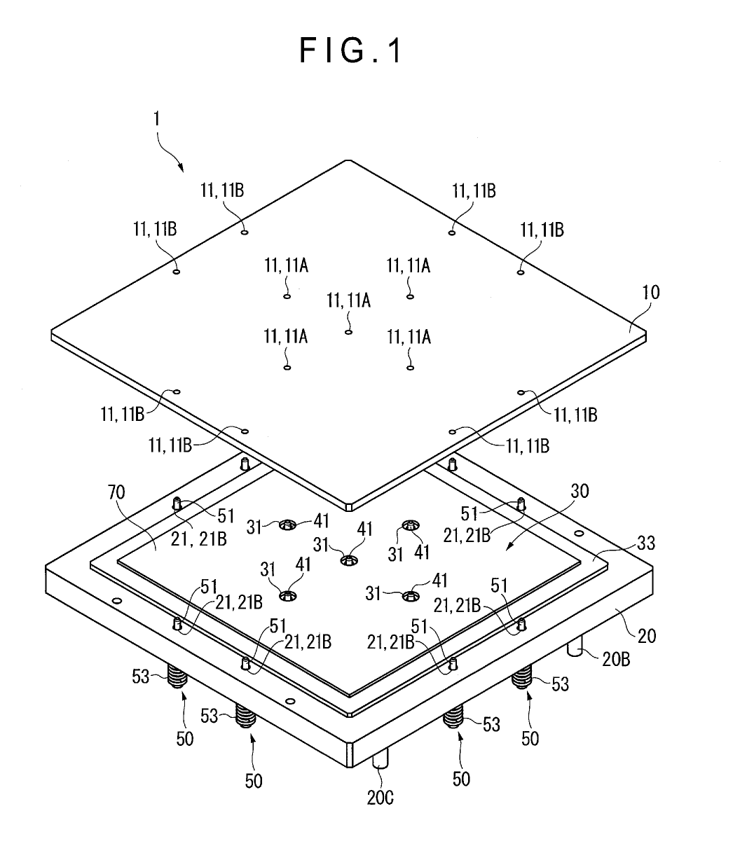

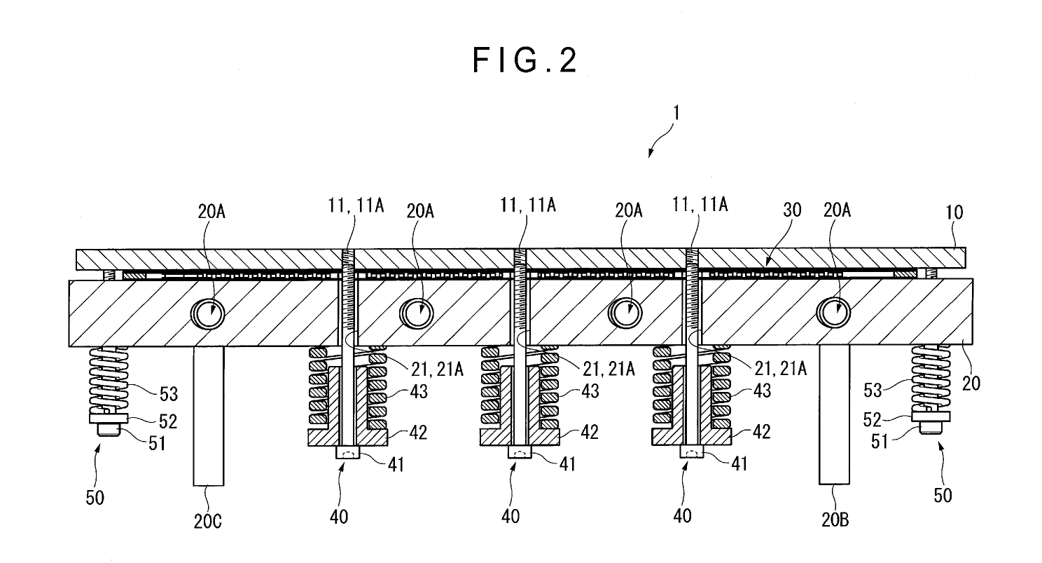

FIG. 1 is an exploded perspective view of a thermoelectric generator 1 according to the first exemplary embodiment. FIG. 2 is a cross-sectional view of the thermoelectric generator 1.

Overall Description of Thermoelectric Generator

As shown in FIGS. 1 and 2, the thermoelectric generator 1, which is formed quadrangular in a planar view, includes: a heat-receiving plate 10 configured to receive heat (shown at an upper side of the figure); a cooling plate 20 kept at a lower temperature than a temperature of the heat-receiving plate 10; and a thermoelectric generation module 30 interposed between the heat-receiving plate 10 and the cooling plate 20. For instance, when the thermoelectric generator 1 is disposed at a burning portion of a burner in a heat-treating furnace, the heat-receiving plate 10 is heated by flame of the burner and a heat energy at this time is converted into electricity.

The heat-receiving plate 10 is, for instance, made of iron, copper or aluminum and is heated to about 280 degrees C. by flame and the like.

The cooling plate 20 is, for instance, made of aluminum and includes a cooling circuit 20A in which a cooling liquid (e.g., cooling water) flows therein. The cooling plate 20 is entirely cooled and kept at about 20 to 40 degrees C. by the cooling liquid. The cooling circuit 20A is connected to a feed pipe 20B and a return pipe 20C of the cooling liquid on an outside of the cooling plate 20.

The thermoelectric generation module 30 will be described later.

A plurality of bolt holes 11 each having an internal thread are provided at and near a center and near a periphery of the heat-receiving plate 10. A plurality of through holes 21 penetrating the cooling plate 20 from a front side to a rear side are provided at and near a center and near a periphery of the cooling plate 20 in a manner corresponding to the bolt holes 11. A plurality of through holes 31 are provided at and near a center of the thermoelectric generation module 30 in a manner corresponding to the bolt holes 11 and the through holes 21.

With use of the bolt holes 11 and the through holes 21, 31, the heat-receiving plate 10 and the cooling plate 20 are fastened together while the thermoelectric generation module 30 is held between the heat-receiving plate 10 and the cooling plate 20. At this time, a first fastener 40 and a second fastener 50 are used as a fastening means.

Five first fasteners 40 are provided to the through holes at and near the center of the thermoelectric generation module 30 in the thermoelectric generator 1. Each of the first fasteners 40 includes: a bolt 41 inserted into each of the bolt holes 11A and the through holes 21A at and near the center among the bolt holes 11 and the through holes 21 and the through holes 31 of the thermoelectric generation module 30; a receiving member 42 having a cylindrical portion in which the bolt 41 is inserted and a flange integrated with the cylindrical portion and having an inverse T-shaped cross section; and a coil spring 43 in which the bolt 41 is inserted and that is interposed between a lower surface of the cooling plate 20 and a spring seat surface of the flange of the receiving member 42, the coil spring 43 being configured to apply a pressing force to the thermoelectric generation module 30 through the heat-receiving plate 10 and the cooling plate 20.

The second fastener 50 includes a pair of second fasteners 50 on each of sides of the thermoelectric generator 1, namely, eight second fasteners 50 (only two of those are shown in FIG. 2). Each of the second fasteners 50 includes: a bolt 51 inserted, from under, in each of the bolt holes 11B and the through holes 21B along each of the sides among the bolt holes 11 and the through holes 21; a ring-shaped receiving member 52 in which the bolt 51 is inserted; and a coil spring 53 in which the bolt 51 is inserted and that is interposed between the lower surface of the cooling plate 20 and a spring seat surface of the receiving member 52 and applies a pressing force to the thermoelectric generation module 30 through the heat-receiving plate 10 and the cooling plate 20.

Herein, a wire diameter and an outer diameter of the coil spring 53 of the second fastener 50 are smaller than a wire diameter and an outer diameter of the coil spring 43 of the first fastener 40. A spring force of the coil spring 53 is smaller than a spring force of the coil spring 43. The second fasteners 50 having a smaller spring force are provided in a pair close to each other on each of the sides of the thermoelectric generator 1 in order to uniform a holding force to be applied to the thermoelectric generation module 30, the holding force being generated when the thermoelectric generation module 30 is held between the heat-receiving plate 10 and the cooling plate 20.

### Description of Thermoelectric Generation Module

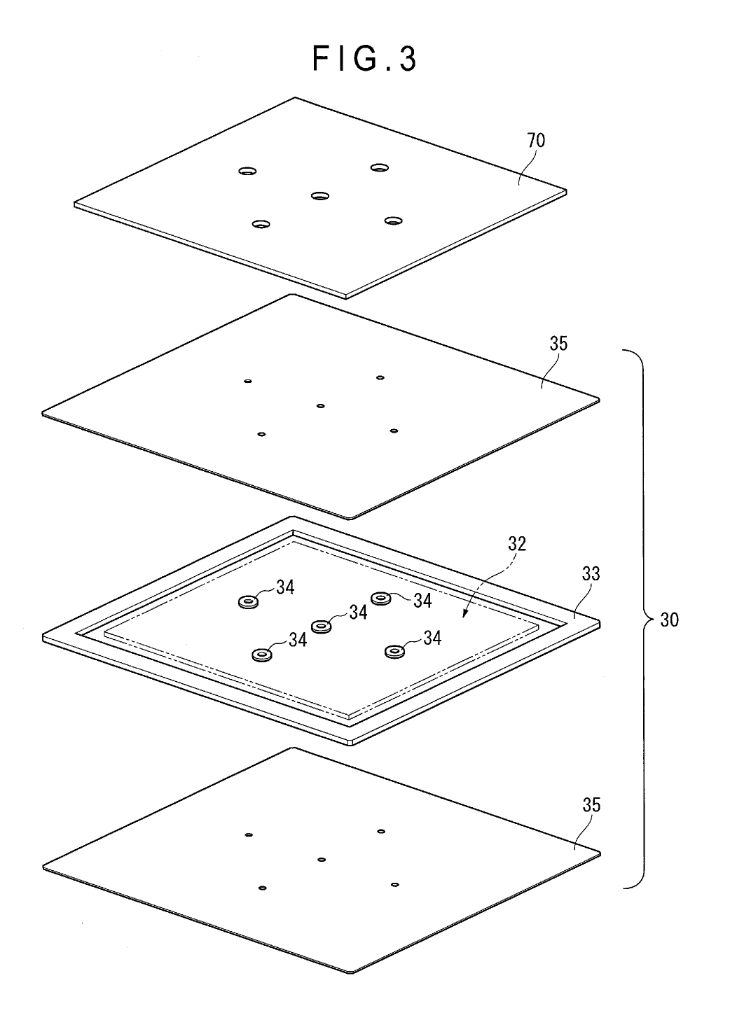

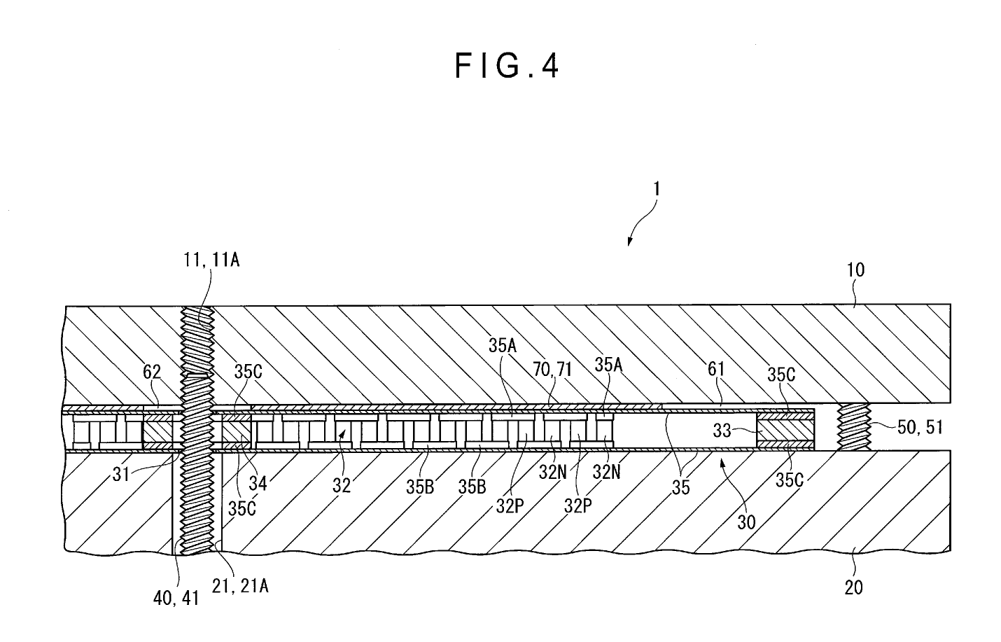

FIG. 3 is an exploded perspective view showing the thermoelectric generation module 30 and a heat transfer sheet 70. FIG. 4 is an enlarged cross-sectional view of a relevant portion of the thermoelectric generator.

As shown in FIGS. 3 and 4, the thermoelectric generation module 30 includes: a plurality of N-type thermoelectric elements 32N and a plurality of P-type thermoelectric elements 32P; a square-ring-shaped outer sealing frame 33 surrounding the thermoelectric elements 32N, 32P and made of metal such as iron, copper and aluminum; ring-shaped inner sealing frames 34 each surrounding the bolt 41 penetrating the through hole 31 and made of metal such as iron, copper and aluminum; and an upper film sheet 35 continuously entirely covering a first side facing the heat-receiving plate 10 of the thermoelectric elements 32N, 32P and the sealing frames 33, 34 and a lower film sheet 35 continuously entirely covering a second side facing the cooling plate 20 of the thermoelectric elements 32N, 32P and the sealing frames 33, 34.

In FIG. 3, the plurality of thermoelectric elements 32N, 32P are shown by a two-dot chain line as a thermoelectric element unit 32. The film sheets 35 respectively covering a top and a bottom of the thermoelectric element unit 32 as described above are in a form of a laminated sheet having a polyimide film and a copper film entirely covering one surface of the polyimide film. The film sheets 35 are respectively provided on the first and second sides of the thermoelectric elements 32N, 32P and the sealing frames 33, 34 with the respective copper films facing the heat-receiving plate 10 and the cooling plate 20. Further, in addition to integrating the thermoelectric elements 32N, 32P and the sealing frames 33, 34 into a unit, each of the film sheets 35 is adapted to absorb a difference in thermal expansion in an in-plane direction (right-left direction in the figure) between the heat-receiving plate 10 to be thermally expanded by receiving heat and the thermoelectric elements 32N, 32P and the sealing frames 33, 34 to be thermally expanded by transferred heat.

As shown in FIG. 4, a plurality of heat-receiving electrodes 35A are formed on an inner surface (an opposite surface of the polyimide film from the copper film) of the film sheet 35 near the heat-receiving plate 10. A plurality of cooling electrode 35B are provided on an inner surface (an opposite surface of the polyimide film from the copper film) of the film sheet 35 near the cooling plate 20. In each of the N-type thermoelectric elements 32N and the P-type thermoelectric elements 32P, an end surface near the heat-receiving plate 10 is connected to the heat-receiving electrode 35A while an end surface near the cooling plate 20 is connected to the cooling electrode 35B. The N-type thermoelectric elements 32N and the P-type thermoelectric elements 32P are electrically connected in series alternately through the heat-receiving electrode 35A and the cooling electrode 35B. A lead wire (illustration is omitted) for transferring generated electricity is connected to a terminal one of the thermoelectric elements 32N, 32P connected in series.

Moreover, a bonding pattern 35C similar to those of the heat-receiving electrode 35A and the cooling electrode 35B is formed on the inner surface of each of the film sheets 35, corresponding to the outer sealing frame 33 and the inner sealing frame 34. By bonding the sealing frames 33, 34 to the bonding pattern 35C by soldering and the like, the sealing frames 33, 34 are firmly bonded to the film sheets 35. A bonding portion of each of the outer sealing frame 33 and the inner sealing frame 34 has a simple square cross section.

### Description of Heat Insulation Layer

In FIG. 4, a first heat insulation layer 61 (an air layer) is formed in a space that is defined between the heat-receiving plate 10 and the thermoelectric generation module 30 and that corresponds to the outer sealing frame 33. Second heat insulation layers 62 (air layers) are also formed in a space that is defined between the heat-receiving plate 10 and the thermoelectric generation module 30 and that corresponds to the inner sealing frames 34. Since the first and scone heat insulation layers 61, 62 are formed, heat received in the heat-receiving plate 10 is not transferred to the cooling plate 20 through the sealing frames 33, 34. Accordingly, the heat received in the heat-receiving plate 10 is entirely transferred through the thermoelectric elements 32N, 32P, thereby enabling to improve a power generation efficiency in the thermoelectric generation module 30.

### Description of Heat Transfer Layer

As shown in FIGS. 3 and 4, a heat transfer layer 71 is formed in a space defined between the heat-receiving plate 10 and the thermoelectric generation module 30 in a manner to circumvent the first heat insulation layer 61 and the second heat insulation layers 62. The heat transfer layer 71 is formed of the heat transfer sheet 70 made of a carbon sheet and the like. Since the heat transfer layer 71 fills the rest of the space between the heat-receiving plate 10 and the thermoelectric generation module 30 other than the first and second heat insulation layers 61, 62, the heat received in the heat-receiving plate 10 can be effectively transferred to the thermoelectric elements 32N, 32P. Moreover, the heat transfer sheet 70 is also adapted to absorb a difference in thermal expansion in a thickness direction (up-down direction in the figure) between the heat-receiving plate 10 thermally expanded by receiving heat and the thermoelectric elements 32N, 32P and sealing frames 33, 34 thermally expanded by transferred heat.

### Description of Manufacturing Procedure

Next, a manufacturing procedure of the thermoelectric generator 1 will be described.

First, the thermoelectric elements 32N, 32P, the outer sealing frame 33, and the inner sealing frames 34 are bonded by soldering and the like between the film sheets 35 in which the heat-receiving electrode 35A, cooling electrode 35B, and bonding pattern 35C are formed by a known circuit pattern forming method, thereby assembling the thermoelectric generation module 30. One of the film sheets 35 of the thermoelectric generation module 30 is disposed on the cooling plate 20 while the heat transfer sheet 70 is disposed on the other of the film sheets 35. Further, the heat-receiving plate 10 is disposed on the heat transfer sheet 70. Thus, the thermoelectric generation module 30 is held between the heat-receiving plate 10 and the cooling plate 20. Subsequently, the heat-receiving plate 10, cooling plate 20, and thermoelectric generation module 30 are mutually fastened by the first and second fasteners 40, 50. Description of treatment of other components such as the lead wire will be omitted.

### Description of Effects

According to the exemplary embodiment, since the thermoelectric generation module 30 is sealed with use of the metallic outer sealing frame 33 and inner sealing frame 34, heat resistance is further improvable, so that a favorable sealing performance is maintainable even when the thermoelectric generator 1 is exposed to high heat. Moreover, since the first heat insulation layer 61 is formed in the space corresponding to the outer sealing frame 33 and the second heat insulation layers 62 are formed in the space corresponding to the inner sealing frames 34 between the heat-receiving plate 10 and the thermoelectric generation module 30, the heat received in the heat-receiving plate 10 is prevented from being transferred to the sealing frames 33, 34, so that the heat amount to be transferred to the cooling plate through the sealing frames 33, 34 can be significantly reduced to improve the electric power generation efficiency.

### Second Exemplary Embodiment

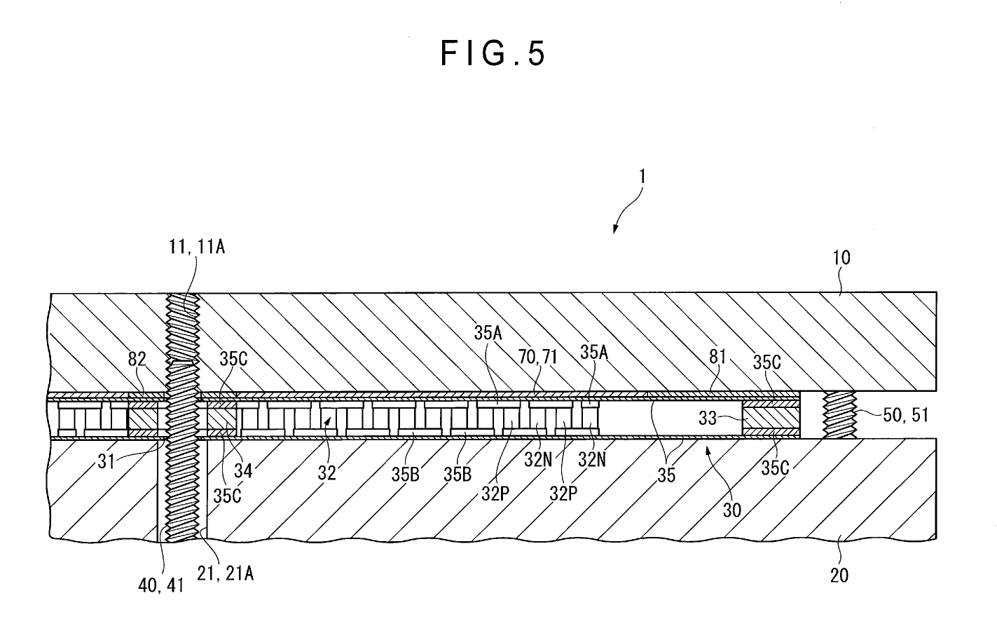

FIG. 5 is a cross-sectional view of the thermoelectric generator 1 according to a second exemplary embodiment of the invention.

In FIG. 5, a first heat insulation layer 81 and a second heat insulation layer 82 in a form of a sheet made of any heat-insulative material (e.g., polytetrafluoroethylene (PTFE) and porous polyimide) are respectively formed corresponding to the outer sealing frames 33, 34 in the space defined between the heat-receiving plate 10 and the thermoelectric generation module 30. The rest of the components of the thermoelectric generator 1 are the same as those in the first exemplary embodiment.

The same effects as in the first exemplary embodiment can be obtained also in the second exemplary embodiment.

### Modification(s)

The scope of the invention is not restricted to the above exemplary embodiments, but includes modifications and improvements as long as an object of the invention can be achieved.

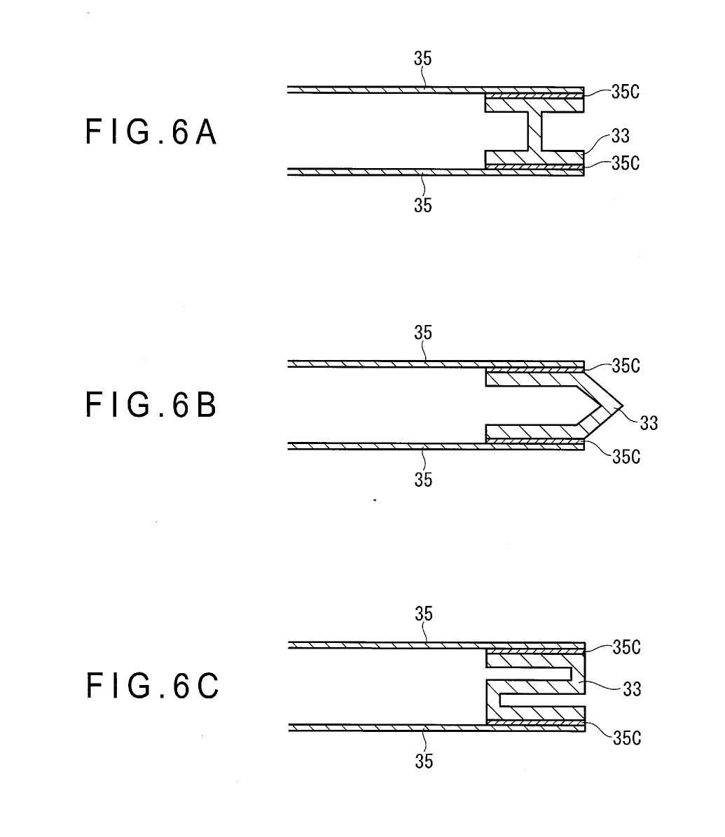

For instance, the cross section of each of the sealing frames 33, 34 is a simple square in the above exemplary embodiments, but not limited to the square. As represented by the outer sealing frame 33 in FIGS. 6A to 6C, the cross section may be a sideways H-shaped cross section (FIG. 6A), a sideways V-shaped or U-shaped cross section (FIG. 6B) and Z-shaped cross section (FIG. 6C), further, although not shown, a sideways M-shaped cross section, a sideways W-shaped cross section or a cross section similar to the above. With the above cross sections, since a cross section of a path through which heat is transferred from the heat receiving side to the cooling side is decreased and a transfer path of the heat is prolonged, the heat transfer can be made difficult.

Moreover, in order to obtain the same effects, a thickness of each of the sealing frames may be sufficiently increased. In this arrangement, when the thickness of each of the sealing frames is larger than a thickness of each of the thermoelectric elements, a step may be formed in the heat-receiving plate and the cooling plate, whereby a position of the bonding portion of each of the thermoelectric elements is differentiated from a position of the bonding portion of each of the sealing frames to absorb a dimensional difference between the thermoelectric elements and the sealing frames.

In the above exemplary embodiments, the heat transfer layer 71 is exemplified by a layer formed of the heat transfer sheet 70 (e.g., carbon sheet), but may be formed from heat conductive grease. In this arrangement, the surrounding first and second heat insulation layers are desirably a solid material (e.g., sheet) instead of the air layer. With this arrangement, the first and second heat insulation layers function as a barrier against the heat conductive grease to enable to prevent the heat conductive grease from leaking out between the heat-receiving plate and the cooling plate.

In the above exemplary embodiments, the thermoelectric generation module 30 of the thermoelectric generator 1 is exemplified by one including a single thermoelectric element unit 32. However, the thermoelectric generation module may include a plurality of thermoelectric element units.

Moreover, as for the first and second fasteners 40, 50 described in the first exemplary embodiment, any suitable structure may be employed for implementation and is not limited to the structure in the above exemplary embodiments.

Further, in the above exemplary embodiments, the second side facing the cooling plate 20 of the thermoelectric elements 32N, 32P and the sealing frames 33, 34 is also covered with the film sheet 35. However, the film sheet may be provided as needed on the second side facing the cooling plate. The film sheet may be omitted as long as electrical insulation between the thermoelectric elements and the cooling plate is maintained.

In the above exemplary embodiments, the sealing frames 33, 34 are soldered to the film sheets 35, but may be bonded by an adhesive agent (e.g., polyimide varnish) usable at a high temperature.

In the above exemplary embodiments, since the first fastener 40 is used, the inner sealing frames 34 each surrounding the bolt 41 of the first fastener 40 are also used and the second heat insulation layers 62 are formed. However, when only the second fastener 50 is used, such an inner sealing frame and second heat insulation layer are unnecessary.

1. A thermoelectric generator comprising:
a heat-receiving plate configured to receive heat;
a cooling plate configured to be kept at a lower temperature than a temperature of the heat-receiving plate;
a thermoelectric generation module interposed between the heat-receiving plate and the cooling plate; and
a fastener inserted through the heat-receiving plate, the cooling plate, and the thermoelectric generation module to fasten the heat-receiving plate, the cooling plate, and the thermoelectric generation module to each other,
wherein the thermoelectric generation module comprises:
a plurality of thermoelectric elements,
one or more electrodes connected to the thermoelectric elements,
an outer sealing frame surrounding the thermoelectric elements and the one or more electrodes,
an inner sealing frame surrounding the fastener, the inner sealing frame being provided within the outer sealing frame,
a first film sheet continuously entirely covering at least a first side of each of the inner sealing frame, the thermoelectric elements, the one or more electrodes, and the outer sealing frame, the first side facing the heat-receiving plate,
a first heat insulation layer provided in a space that is defined between the heat-receiving plate and the thermoelectric generation module and that corresponds to the outer sealing frame,
a second heat insulation layer provided in a space that is defined between the heat-receiving plate and the thermoelectric generation module and that corresponds to the inner sealing frame, and
a heat transfer layer provided in a space that is defined between the heat-receiving plate and the thermoelectric generation module and that corresponds to the thermoelectric elements and the one or more electrodes,
wherein the heat transfer layer is configured to circumvent the first and second insulation layers to thereby transfer heat from the heat-receiving plate to the thermoelectric generation module.

2. (canceled)

3. (canceled)

4. (canceled)

5. The thermoelectric generator according to claim 1, wherein
the thermoelectric generation module is interposed between the heat-receiving plate and the cooling plate while being pressed by the heat-receiving plate and the cooling plate, and
the fastener comprises a coil spring configured to apply a pressing force to the thermoelectric generation module through the heat-receiving plate and the cooling plate.

6. The thermoelectric generator according to claim 1, wherein
the outer sealing frame is bonded to the first film sheet.

7. The thermoelectric generator according to claim 1, wherein
the inner sealing frame is bonded to the first film sheet.

8. The thermoelectric generator according to claim 1, wherein
the first film sheet comprises film sheets each comprising a polyimide film and a copper film entirely covering one surface of the polyimide film, and
the film sheets are respectively provided on the first side facing the heat-receiving plate and a second side facing the cooling plate of the thermoelectric elements and the outer sealing frame with the respective copper films facing the heat-receiving plate and the cooling plate.

9. The thermoelectric generator according to claim 1, wherein the heat transfer layer is provided at all portions between the heat-receiving plate and the thermoelectric generation module corresponding to the thermoelectric elements and the one or more electrodes.

10. The thermoelectric generator according to claim 1, wherein the first film sheet is extended in an in-plane direction.

11. The thermoelectric generator according to claim 1, wherein the one or more electrodes are positioned between the first film sheet and the thermoelectric elements.

12. The thermoelectric generator according to claim 1, wherein the inner sealing frame comprises a plurality of inner sealing frames that are provided within the outer sealing frame.

13. The thermoelectric generator according to claim 1, further comprising:
a second film sheet continuously entirely covering at least a second side of each of the inner sealing frame, the thermoelectric elements, the one or more electrodes, and the outer sealing frame, the second side facing the cooling plate.

14. The thermoelectric generator according to claim 13, wherein the outer sealing frame, the inner sealing frame, the first film sheet, and the second film sheet define a sealed space in which the thermoelectric elements and the one or more electrodes are disposed.

15. The thermoelectric generator according to claim 14, wherein the thermoelectric elements and the one or more electrodes are attached to the outer sealing frame and the inner sealing frame via the first and second film sheets.
